(19) United States
(12) Patent Application Publication
(10) Pub. No.: US 2006/0193981 A1
(43) Pub. Date: Aug. 31, 2006

(54) Apparatus and method for masking vapor phase aluminide coating to achieve internal coating of cooling passages

(75) Inventors: Gary Eugene Wheat, Madisonville, KY (US); Terri Kay Brown, Central City, KY (US); Carl H. Snyder, Madisonville, KY (US); Daniel Franklin, Madisonville, KY (US)

Correspondence Address: MCNEES WALLACE & NURICK LLC, 100 PINE STREET, P.O. BOX 1166, HARRISBURG, PA, 17108-1166, US

(73) Assignee: GENERAL ELECTRIC COMPANY, Schenectady, NY (US)

(21) Appl. No.: 11/208,705

(22) Filed: Aug. 22, 2005

Related U.S. Application Data
(63) Continuation-in-part of application No. 11/065,824, filed on Feb. 25, 2005.

(51) Int. Cl. C23C 16/00

(52) U.S. Cl. 427/248.1; 118/720

(57) ABSTRACT

The present invention is an apparatus for masking an exterior dovetail surface of a turbine airfoil for use in coating a turbine airfoil, wherein the apparatus comprises a turbine airfoil. The apparatus comprises a plurality of dovetail graphite sponge boot sections. The boot comprises a first interior surface assembled to the turbine airfoil to contact substantially all of an exterior dovetail surface of the turbine airfoil, while leaving exposed an exterior airfoil flowpath surface, a root portion of the exterior dovetail surface and an interior passageway surface. The boot further comprises second interior channel surfaces defining interior boot channels, a first exterior surface, a first aperture in the first exterior surface, the turbine airfoil extending out of the boot through the first exterior surface, a second exterior surface, second apertures in the second exterior surface in fluid communication with the interior cavity, the interior passageway surface, and an exterior environment.

### CROSS-REFERENCE TO RELATED APPLICATIONS

This Application is a continuation-in-part of application Ser. No. 11/065,824, filed Feb. 25, 2005, which is incorporated by reference herein in its entirety.

### FIELD OF THE INVENTION

The present invention relates generally to coating gas turbine engine components with aluminum and/or co-deposited metals, and, more particularly, to a method for masking components during aluminiding or co-deposition of aluminum to prevent deposition of aluminum onto preselected surfaces of such airfoils.

### BACKGROUND OF THE INVENTION

To provide protection against high temperatures and corrosive effects of hot gases in gas turbine engines, turbine airfoils have been subjected to aluminide coating. Aluminide coating on the flowpath surfaces, platform, angel wing and respective edges provides oxidation and corrosion resistance and enhances the performance life of the airfoil component. For some components, it is necessary to avoid coating the dovetail section below the platform of turbine airfoil components because coating can adversely affect fatigue life of the dovetail section. Furthermore, coating the dovetail section is not necessary because in service this section is not in the hot gas flowpath, as is the airfoil section. It is therefore necessary to mask certain sections of the component to prevent coating such sections while allowing coating of other sections.

Two methods for coating turbine airfoils are a pack-cementation process and a vapor phase aluminide process. These are diffusion coating processes that use aluminum halides (AlXₙ), where X is a halide, such as fluoride, chloride, etc., and/or ammonium halides (NH₄X), where X is a halide, such as fluoride, chloride, etc., to apply an oxidation-/corrosion-resistant, aluminum-rich layer to the component surface. The pack-cementation process involves sequential steps of degreasing, taping and sealing holes, waxing, loading box, slurry application, sealing, packing, running, unloading and blowoff, water cleaning, and aging. This process utilizes an activated Al-rich powder packed tightly around the airfoil section to facilitate coating, while the areas below the platform are packed with an inert powder containing calcined alumina and concentrations of Ni⁺² and Cr⁺³ similar to the parent metal to avoid possible coating deposition, as well as alloy depletion and inter-granular attack. The process yields an aluminide coating that is brittle yet functional for prohibiting corrosion. This process is labor-intensive and operator-dependent, and tends to plug cooling holes and leave excessive amounts of foreign material on the airfoils. It also requires a final heat treatment, without which the coating is too brittle.

The vapor phase aluminide process yields a ductile aluminide coating, which requires minimal final heat treatment. The vapor phase aluminide process does not require blow-off or water cleaning operations, thus reducing labor and material costs. One disadvantage of this process, however, is that coating must be removed from the dovetail sections by grinding, and such grinding also removes the beneficial platform edge and angel wing edge coating. Thus, there is a need for an effective masking technique that facilitates secure masking of a plurality of turbine airfoil components during vapor phase diffusion coating processes.

What is needed is a dovetail section receptacle apparatus for use in vapor phase diffusion coating of turbine airfoils that permits the effective coating of the internal cooling passages of turbine airfoils without requiring extensive grinding of the aluminide coating from areas of the component where such coating would be disadvantageous. The present invention provides this advantage as well as other related advantages.

### SUMMARY OF THE INVENTION

The present invention is an apparatus for masking an exterior dovetail surface of a turbine airfoil for use in coating a turbine airfoil, wherein the apparatus comprises a turbine airfoil comprising an exterior airfoil flowpath surface, an interior passageway surface, the interior passageway surface being in fluid communication with an exterior environment through a plurality of cooling holes in the exterior airfoil flowpath surface, a platform comprising an exterior platform surface, and an exterior dovetail surface, the exterior dovetail surface comprising a main portion and a root portion, air intake holes being disposed in the root portion, the air intake holes being in fluid communication with the interior passageway surface. The apparatus further comprises a plurality of dovetail graphite sponge boot sections, the boot sections having a preselected geometry such that the sections are assembled into a dovetail graphite sponge boot. The boot comprises a first interior surface, the first interior surface defining a first interior cavity, the first interior surface assembled to the turbine airfoil to contact substantially all of the exterior dovetail surface of the turbine airfoil, while leaving exposed the exterior airfoil flowpath surface, the root portion of the exterior dovetail surface and the interior passageway surface. The boot further comprises second interior channel surfaces, each second interior channel surface defining an interior boot channel, each interior boot channel being in fluid communication with a root portion hole and an exterior environment. The boot further comprises a first exterior surface, a first aperture in the first exterior surface, the turbine airfoil extending out of the boot through the first exterior surface, a second exterior surface, second apertures in the second exterior surface, each second aperture being in fluid communication with one interior boot channel, the root portion holes, the interior passageway surface, and the exterior environment, and first sidewalls connecting the first and second exterior surfaces.

The present invention is also a turbine airfoil coating assembly for vapor phase diffusion coating of an exterior airfoil flowpath surface, a plurality of interior passageway surfaces, and an exterior platform surface of a turbine airfoil, while avoiding coating of substantially all of an exterior dovetail surface thereof, the assembly comprising a turbine airfoil. The turbine airfoil comprises an exterior flowpath surface, a platform section having an exterior platform surface, a plurality of interior passageway surfaces, the plurality of interior passageway surfaces defining a plurality of interior passageways, a dovetail section having an exterior dovetail surface, the dovetail surface comprising a main portion and a root portion, the plurality of interior passageways being in fluid communication with an exterior environment through a first plurality of cooling holes in the exterior flowpath surface and a second plurality of air intake holes in the root portion of the dovetail surface. The assembly further comprises a dovetail graphite sponge boot. The boot comprises a plurality of sections, a first interior boot surface, the first interior boot surface defining an interior cavity, the dovetail section positioned within the interior cavity, second interior channel surfaces, the second interior channel surfaces defining interior boot channels, the interior boot channels being in fluid communication with the air intake holes and an exterior environment, a first exterior boot surface, a first aperture in the first exterior boot surface, wherein the turbine airfoil extends out of the first exterior boot surface through the first aperture, a second exterior boot surface, second apertures in the second exterior boot surface in fluid communication with the interior boot channels, the plurality of interior passageways of the turbine airfoil and an exterior environment, and first sidewalls connecting the first and second exterior boot surfaces.

The present invention is also a method for applying a diffusion aluminide coating to a turbine airfoil comprising the step of providing a vapor phase diffusion aluminiding apparatus. The method further comprises the step of providing a plurality of graphite sponge boot sections, the graphite sponge boot sections being configured such that the graphite boot sections are capable of being assembled to form a graphite sponge boot comprising a first interior surface, the first interior surface defining a first interior cavity, second interior channel surfaces, each second interior channel surface defining an interior boot channel, each interior boot channel being in fluid communication with the first interior cavity and an exterior environment, a first exterior surface, a first aperture in the first exterior surface, the turbine airfoil extending out of the boot through the first exterior surface, a second exterior surface, second apertures in the second exterior surface in fluid communication with the interior boot channels, and the exterior environment, and first sidewalls connecting the first and second exterior surfaces. The method further comprises the step of providing a boot receptacle, the boot receptacle comprising a third interior receptacle surface defining an interior receptacle chamber, a top, a first opening in the top of the receptacle permitting the insertion of the boot into the chamber, a bottom, third interior receptacle channel surfaces, the third interior channel surfaces defining interior receptacle channels, the interior receptacle channels being in fluid communication with the interior boot channels and the exterior environment, second openings in the bottom in fluid communication with the interior receptacle channels and the exterior environment, and second sidewalls connecting the top and the bottom. The method further comprises providing a turbine airfoil, the turbine airfoil comprising an airfoil section, a platform section, a dovetail section opposed to the airfoil section, the airfoil section extending in a first direction from the platform section, the dovetail section extending in a second direction from the platform section, the airfoil section having an exterior flowpath surface, the platform section having an exterior platform surface, a plurality of interior passageway surfaces, the plurality of interior passageway surfaces defining a plurality of cooling passageways and being in fluid communication with an exterior environment through a first plurality of cooling holes in the exterior flowpath surface and a second plurality of air intake holes in the root portion of the dovetail section; the dovetail section having an exterior dovetail surface, the dovetail surface comprising a main portion and a root portion, the plurality of interior passageways being in fluid communication with an exterior environment through a first plurality of cooling holes in the exterior flowpath surface and a second plurality of air intake holes in the root portion of the dovetail section. The method further comprises applying a barrier coating to the root portion of the dovetail surface, the barrier coating comprising holes such that the root portion of the dovetail surface is covered with the barrier coating and the second plurality of air intake holes remain in fluid communication with the exterior environment. The method further comprises placing the graphite sponge boot sections around the dovetail section of the turbine airfoil such that substantially all of an exterior dovetail surface, excepting the root portion of the exterior dovetail surface, is in contact with the dovetail graphite sponge boot, such that all of the cooling holes are in fluid communication with an exterior environment. The method further comprises inserting the dovetail graphite sponge boot into a boot receptacle such that all of the cooling holes are in fluid communication with an exterior environment; inserting the boot receptacle into a vapor phase diffusion aluminiding apparatus. The method further comprises applying a diffusion aluminide layer to the exterior flowpath surface, the exterior platform surface, and the plurality of interior passageway surfaces of the turbine airfoil.

This process yields airfoil components having an aluminide coating on the exterior airfoil flowpath surfaces of the airfoil section, platform upper surfaces, the platform edges, and angel wing edges where oxidation and corrosion resistance are required, and advantageously having no coating on dovetail sections. With this new masking technique, it is possible to coat components with the vapor phase aluminide process which previously would be coated only by the pack cementation process. Furthermore, disadvantages of the pack cementation process such as plugged holes, external and internal foreign materials, coating brittleness, labor intensity, and slow production times are avoided. The process of the invention is also superior to prior vapor phase aluminiding processes, which were unable to effectively coat all of the exterior platform surfaces while avoiding deposition of coating onto the dovetail sections. The new process therefore produces a better product more efficiently than the prior processes.

An advantage of the present invention is that a vapor phase diffusion aluminide coating can be applied to external surfaces and the surfaces of the internal cooling passages of a turbine airfoil without the adverse aluminization of a dovetail portion of the turbine airfoil.

Another advantage of the present invention is that extensive masking of the dovetail portion of the turbine airfoil is unnecessary.

Yet another advantage of the present is that platform and angel wing edges of turbine airfoils, where oxidation and corrosion resistance are required, are readily aluminided.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 is a perspective view of one type of turbine blade.

FIG. 2 is a cross-section of the turbine blade of FIG. 1, showing the cooling passages within the turbine blade.

FIG. 3 is a perspective view of a second type of turbine blade.

FIG. 4 is a perspective view of the turbine blade of FIG. 3, showing the cooling passages within the turbine blade.

FIG. 5 is a perspective and partial section view of the dovetail graphite sponge boot of the present invention.

FIG. 6 is a perspective and partial section view of the boot receptacle of the present invention.

FIG. 7 is a perspective and partial section view of the dovetail graphite sponge boot of the present invention positioned within the boot receptacle of the present invention.

FIG. 8 is a perspective and partial section view of the turbine blade of FIGS. 2 and 3, positioned within the graphite sponge boot and boot receptacle of the present invention.

### DETAILED DESCRIPTION OF THE INVENTION

The present invention is directed to a masking apparatus and a masking method that is designed to allow the use of a vapor phase aluminization (VPA) process for the deposition of a diffusion aluminide coating on the surface of a turbine airfoil. Such turbine airfoils generally comprise base materials of iron base superalloys, nickel base superalloys, cobalt base superalloys, and combinations thereof.

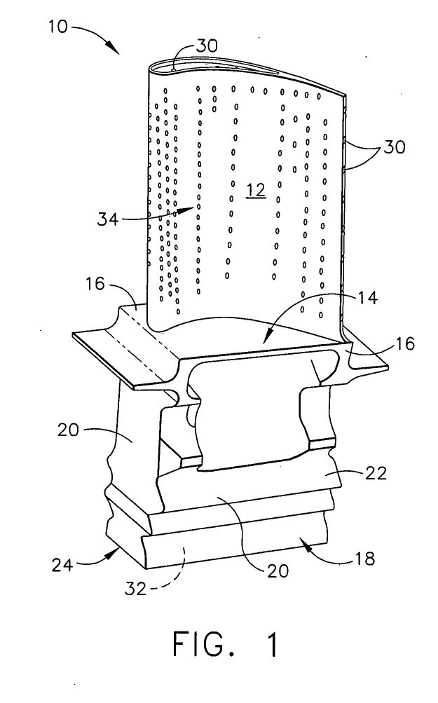

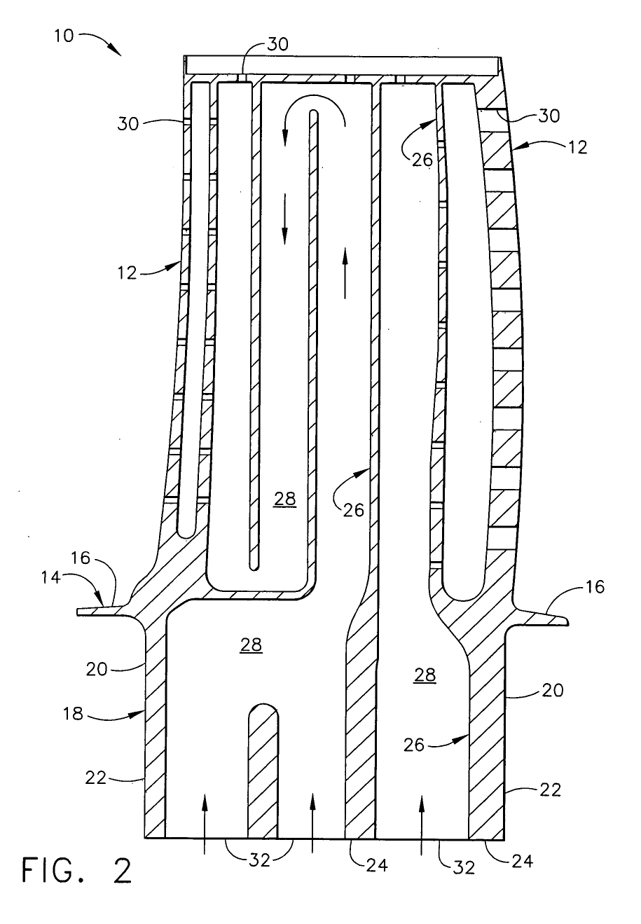

One embodiment of a turbine airfoil that can be used with the apparatus of the present invention is turbine blade 10 shown in FIG. 1 and FIG. 2. As is known in the art, the turbine blade 10 has three sections, an airfoil section 34, a platform section 14, and a dovetail section 18. The airfoil section has exterior flowpath surfaces 12 with one side being the suction side and the opposite side being the pressure side. The platform section has platform exterior surfaces 16. The dovetail section has exterior (or ground) surfaces 20. There are two portions to the exterior dovetail surface, the main portion 22 and the root portion 24 the main portion 22 being positioned between the platform section and the root 24 section. As shown in FIG. 2, a plurality of interior cooling passageway surfaces 26 define a plurality of interior cooling passageways 28, which serve to keep the blade 10 cool during normal engine operation as cooling air from the external source, such as the compression is introduced into the passages and flows into the air intake holes 32 in the root portion 24, through the interior cooling passageways 28 and out the cooling holes 30. The surfaces of the turbine blade 10 that require coating are the exterior flowpath surfaces 12, the platform exterior surfaces 16, and the interior cooling passageway surfaces 26. The exterior dovetail surfaces 20 should not be coated as such coating adversely affects the functionality of the dovetail section 18 of the turbine blade 10.

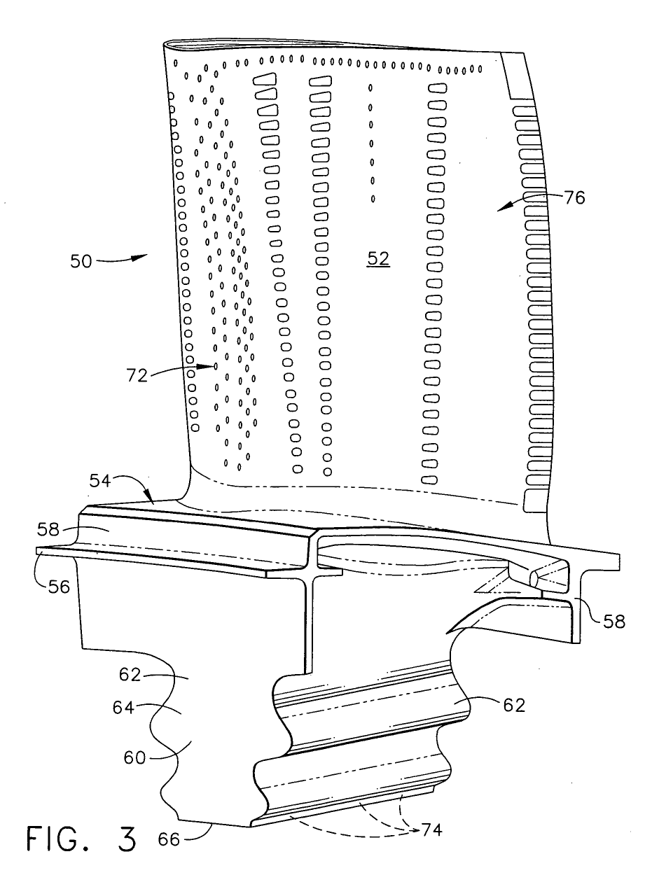

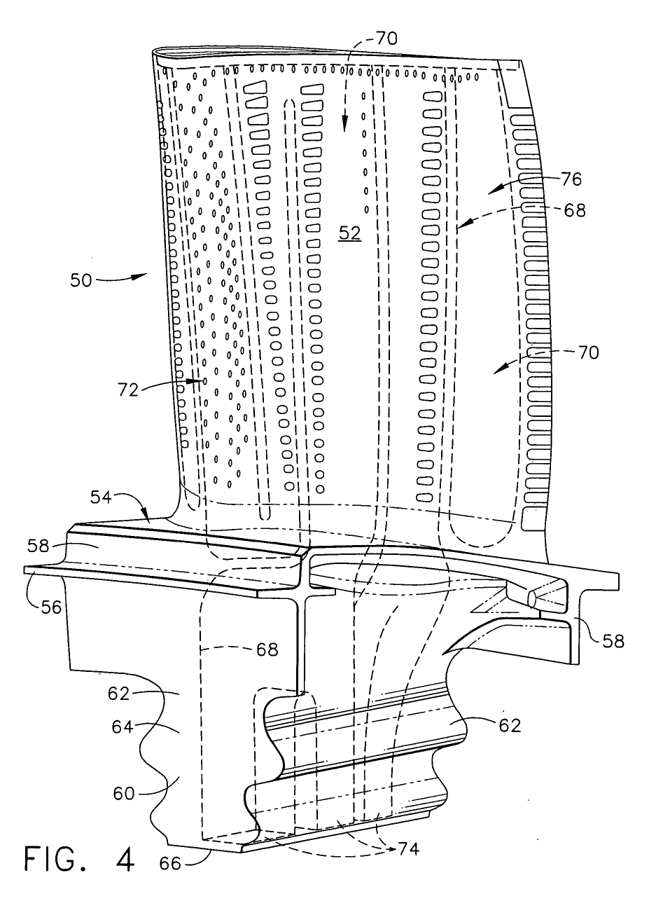

The invention is also applicable to turbine airfoils having a stepped platform configuration, such as turbine blade 50 shown in FIG. 3 and FIG. 4. As is known in the art, the turbine blade 50 has three sections, an airfoil section 76, a platform section 54, and a dovetail section 60. The airfoil section has exterior flowpath surfaces 52. In this type of turbine blade 50, the platform section 54 has an angel wing extension 56. The platform section has platform exterior surfaces 58. The dovetail section has exterior surfaces 62. There are two portions to the exterior dovetail surface, the main portion 64 and the root portion 66. As shown in FIG. 4, a plurality of interior cooling passageway surfaces 68 define a plurality of interior cooling passageways 70, which serve to keep the blade 50 cool during normal engine operation as cooling air flows into the air intake holes 74 in the root portion 66, through the interior cooling passageways 70 and out the cooling holes 72. Again, the surfaces of the turbine blade 50 that require an environmental coating are the exterior flowpath surfaces 52, the platform exterior surfaces 58, and the interior cooling passageway surfaces 68. The exterior dovetail surfaces 62 should not be coated with an environmental coating, as such coating adversely affects the functionality of the dovetail section 60 of the turbine blade 50. The present invention is also applicable to other airfoils including, for example, stator vane assemblies where it may be desirable to coat airfoil flowpath surfaces as well as inner and outer bands of the assembly.

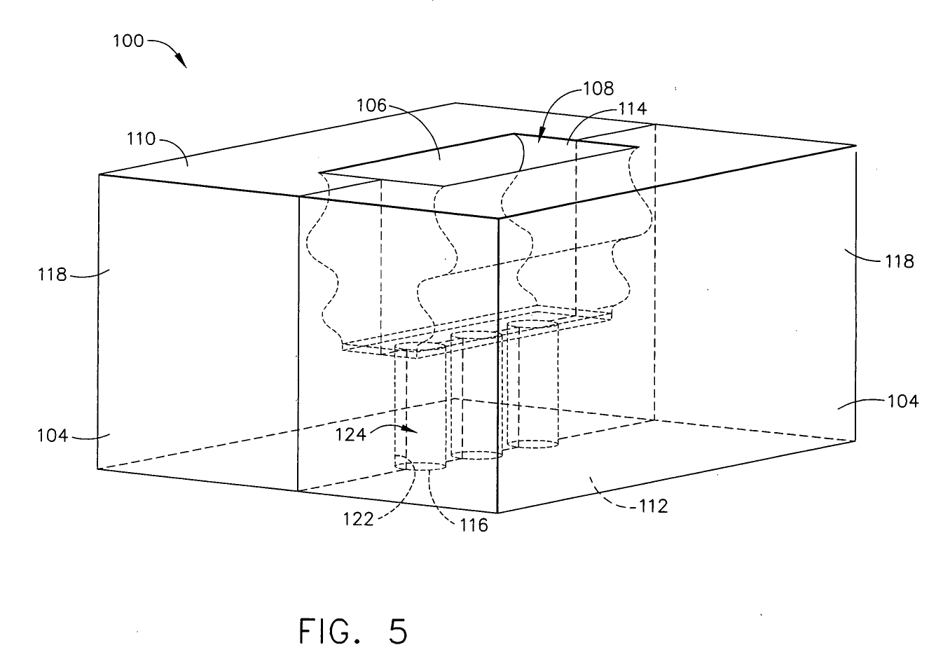

In order to prevent the deposition of the aluminide of the VPA process onto airfoil surfaces that would be adversely affected by such a deposition, a graphite sponge boot 100, as shown in FIG. 5 is designed to be placed around the dovetail section 60 of a turbine blade 50. The dovetail boot and boot receptacle of the present invention may also be used for turbine blade 10. The use of the graphite sponge boot 100 facilitates VPA coating of the exterior flowpath surfaces 52, the platform exterior surfaces 58, and the interior cooling passageway surfaces 68. The graphite sponge boot 100 comprises preformed aerated graphite foam, which is about 99.99% pure graphite. Since aerated graphite does not react with the superalloy substrate material of the dovetail section 60 in any substantial manner, the use of aerated graphite in the boot 100 does not adversely affect the properties of the dovetail section 60 during the VPA process. If the graphite was not aerated, an unacceptable amount of carbon could be transferred into the dovetail 60 during the VPA process. Graphite is also preferred because it contracts upon heating to VPA coating temperatures, which contraction cooperates with the expansion of the airfoils upon heating to maintain contact of the boot 100 with the dovetail section 60. The aerated graphite also is capable of withstanding elevated vapor phase aluminiding temperatures on the order of about 1800° F. to about 2100° F. (about 980° C. to about 1150° C.). Graphite is also essentially inert to aluminide coating and does not readily accept aluminum when exposed to the VPA process.

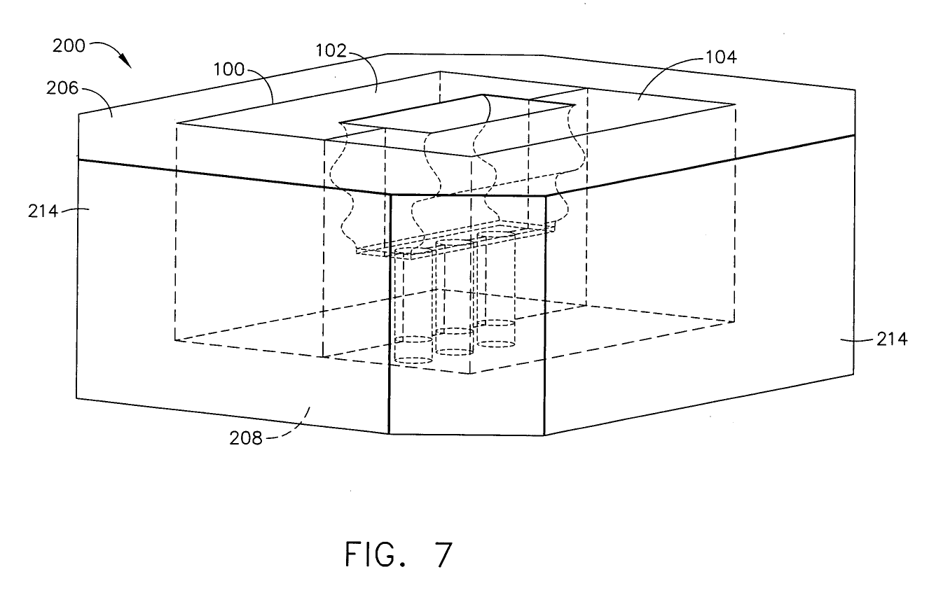

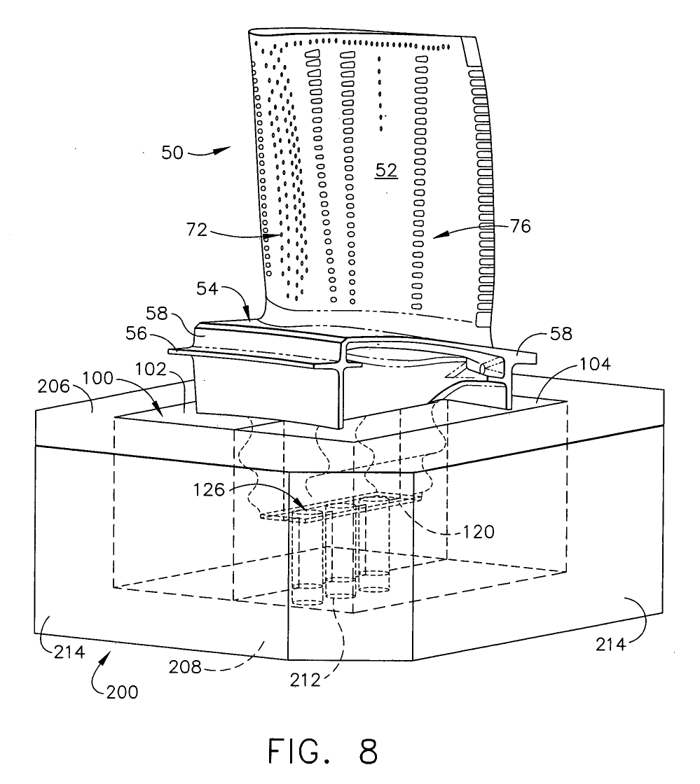

As shown in FIG. 5, FIG. 7 and FIG. 8, the graphite sponge boot 100 comprises a plurality of sections 102, 104 such that the graphite sponge boot sections can be placed around the dovetail section 60 of the turbine blade 50, so that the main portion 64 of the dovetail surface 62 is in contact with the dovetail graphite sponge boot 100. The assembled graphite sponge boot 100 comprises an interior surface 106 that defines an interior cavity 108. The assembled graphite sponge boot 100 further comprises second interior channel surfaces 122 that define interior boot channels 124. The boot 100 also has a first exterior surface 110 having an aperture 114, a second exterior surface 112 having an aperture 116 and sidewalls 118 connecting the first exterior surface 110 and the second exterior surface 112. As shown in FIG. 8, the dovetail section 60 is positioned within the interior cavity 108 and the airfoil section extends away from the aperture 114 in the first exterior surface 110. The apertures 116 of the interior boot channels 124 in the second exterior surface 112 are in fluid communication with the outside environment.

As also shown in FIG. 8, the root portion 66 of the dovetail surface 62 is not in contact with the interior surface 106 so that fluid communication can be maintained between the outside environment and the interior passageway surfaces 68. However, since the root portion 66 of the dovetail surface 62 should not be coated with a diffusion aluminide surface, the root portion 66 should be coated with a barrier layer that prevents diffusion aluminide vapor from contacting the root portion 66, but which does not prevent diffusion aluminide vapor from flowing into air intake holes 74. A preferred barrier layer is a putty or tape strip 120, which contains metallic powder and/or metallic oxide powder. The strip 120 itself acts as a physical barrier while the metallic or metallic oxide component powder serves a gettering function to attract aluminide coating vapor. The strip 120 comprises holes 126 that are in fluid communication with the air intake holes 74, the interior boot channels 124 and the exterior environment. The strip 120 is preferably a putty or tape strip comprising nickel powder and chromium oxide powder or a putty or tape strip comprising nickel powder and aluminum oxide powder. Such putty strip is available as M-1 (nickel/chromium oxide) or M-7 (nickel/aluminum oxide) grade putty strip available from Chromalloy of Israel under the trade designation “T-Block.” This strip 120 is disposed of after each coating operation to avoid release of gettered aluminide during subsequent coating operations. In a preferred embodiment, the strip 120 is about 3/16 inch thick.

Once the dovetail section 60 is positioned within the boot 100, the boot 100 is inserted into a boot receptacle 200 for placement into a VPA apparatus. The boot receptacle 200 holds together the boot sections 102, 104. As with the boot 100, graphite is the preferred material for the boot receptacle 200 for the because it is capable of withstanding elevated vapor phase aluminiding temperatures on the order of about 1800° F. to about 2100° F. (about 980° C. to about 1150° C.) and because it is also essentially inert to aluminide coating and does not accept aluminum when exposed to the VPA process. However, the boot receptacle 200 does not have to comprise aerated graphite, as it is not in contact with the dovetail 60.

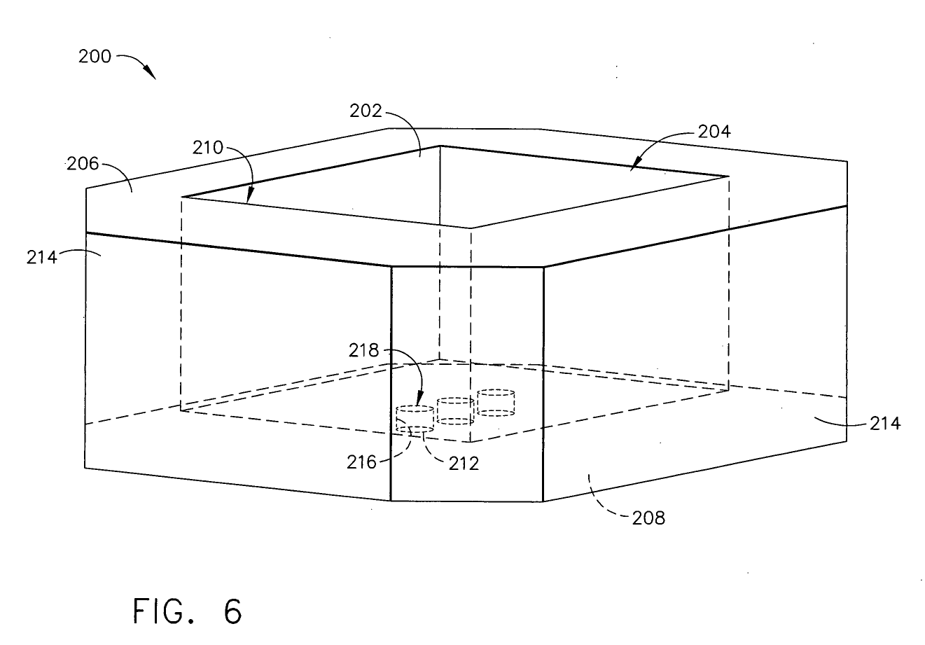

As shown in FIG. 6, FIG. 7, and FIG. 8, the boot receptacle 200 comprises an interior receptacle surface 202, which defines an interior chamber 204. The receptacle 200 has a top 206 and an opening 210 in the top 206 to receive the boot 100. The receptacle 200 also has a bottom 208. Interior boot channel surfaces 122 define interior boot channels 124. Openings 212 in the bottom 208 permit aluminiding vapor to flow through the openings 212, through the interior boot channels 124, and into the air intake holes 74. Sidewalls 214 connect the top 206 with the bottom 208.

Once the dovetail section 60 of the blade 50 is placed into the graphite sponge boot 100 and the graphite sponge boot 100 is placed into the boot receptacle 200, the entire blade coating apparatus, including the blade 50, the graphite sponge boot 100 and the boot receptacle 200 is placed into a VPA apparatus and the VPA process is run as known in the art. During the VPA process, aluminiding vapor from the VPA process enters air intake holes 74 and cooling holes 72 and travels through the interior cooling passageways 70, advantageously coating the interior cooling passageway surfaces 68 with a diffusion aluminide coating. The VPA process also advantageously coats all of the other exposed portions of the blade 50, including the exterior flowpath surfaces 52 and the exterior platform surfaces 58, without coating either the main portion of the dovetail surface 64 or the root portion of the dovetail surface 66.

Once the VPA process is complete, the entire blade coating apparatus is removed from the VPA apparatus, the blade 50 and boot 100 are removed from the boot receptacle 200, and the blade 50 is removed from the boot 100. The strip 120 is removed from the blade 50 and the blade 50 may be brushed or water cleaned to remove residual material.

The graphite sponge boot 100 and boot receptacle 200 of the present invention may be sized and configured to work with any appropriate airfoil component, including a wide variety of turbine blades and stator vane assemblies. With respect to the graphite sponge boot 100, the geometry and size is preselected based on coating specifications of the specific airfoil component being manufactured. For example, the specifications for some turbine blades require that no aluminide coating be present below the sides of the platform. For such a component, the sponge boot 100 is configured so that the entire surface area of the turbine blade, with the exception of the root portion of the dovetail, which is sealed with putty strip 120, below the sides of the platform contacts the interior surface 106.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but

What is claimed is:

1. An apparatus for masking an exterior dovetail surface of a turbine airfoil for use in coating a turbine airfoil, the apparatus comprising:
a turbine airfoil comprising:
an exterior airfoil flowpath surface;
an interior passageway surface;
a platform comprising an exterior platform surface; and
an exterior dovetail surface, the exterior dovetail surface comprising a
main portion and a root portion;
a plurality of dovetail graphite sponge boot sections, the boot sections having a preselected geometry such that the sections are assembled into a dovetail graphite sponge boot, the boot comprising:
a first interior surface, the first interior surface defining a first interior cavity, the first interior surface assembled to the turbine airfoil to contact substantially all of the exterior dovetail surface of the turbine airfoil, while leaving exposed the exterior airfoil flowpath surface, the root portion of the exterior dovetail surface and the interior passageway surface;
a first exterior surface;
a first aperture in the first exterior surface, the turbine airfoil extending out of the boot through the first exterior surface;
a second exterior surface;
a second aperture in the second exterior surface in fluid communication with the interior cavity, the interior passageway surface, and an exterior environment; and
first sidewalls connecting the first and second exterior surfaces.

2. The apparatus of claim 1, the apparatus further comprising:
a barrier coating on the root portion of the exterior surface, wherein the barrier coating does not block the interior passageway surface from being in fluid communication with the second aperture of the hoot.

3. The apparatus of claim 1, the apparatus further comprising:
a boot receptacle receiving the boot comprising:
a second interior receptacle surface, the second interior receptacle surface defining a chamber, the second interior receptacle assembled to the boot to contact the boot;
a top;
a first opening at the top of the receptacle;
a bottom;
a second opening in the bottom, the second opening being in fluid communication with the interior cavity of the boot and the exterior environment; and
second sidewalls connecting the first and second exterior surfaces.

4. The apparatus of claim 1, wherein the platform has a stepped configuration.

5. The apparatus of claim 1, wherein the platform further comprises angel wing extensions.

6. The apparatus of claim 2, wherein the barrier coating is selected from the group consisting of a putty strip and a tape strip.

7. The apparatus of claim 6, wherein the barrier coating further comprises a barrier coating material selected from the group consisting of metallic power, metal powder, and combinations thereof.

8. The apparatus of claim 7, wherein the barrier coating material further comprises nickel powder and chromium oxide powder.

9. The apparatus of claim 7, wherein the barrier coating material further comprises nickel powder and aluminum oxide powder.

10. A turbine airfoil coating assembly for vapor phase diffusion coating of an exterior airfoil flowpath surface, a plurality of interior passageway surfaces, and an exterior platform surface of a turbine airfoil, while avoiding coating of substantially all of an exterior dovetail surface thereof, the assembly comprising:
a turbine airfoil, the turbine airfoil comprising:
an exterior flowpath surface;
a platform section having an exterior platform surface;
a plurality of interior passageway surfaces, the plurality of interior passageway surfaces defining a plurality of interior passageways;
a dovetail section having an exterior dovetail surface, the dovetail surface comprising a main portion and a root portion;
the plurality of interior passageways being in fluid communication with an exterior environment through a first plurality of cooling holes in the exterior flowpath surface and a second plurality of air intake holes in the root portion of the dovetail surface;
a dovetail graphite sponge boot, the boot comprising:
a plurality of sections;
a second interior boot surface, the second interior boot surface defining an interior cavity, the dovetail section positioned within the interior cavity;
a first exterior boot surface;
a first aperture in the first exterior boot surface, wherein the turbine airfoil extends out of the first exterior boot surface through the first aperture;
a second exterior boot surface;
a second aperture in the second exterior boot surface in fluid communication with the plurality of interior passageways of the turbine airfoil and an exterior environment; and
first sidewalls connecting the first and second exterior boot surfaces.

11. The turbine airfoil coating assembly of claim 10, the assembly further comprising:
a boot receptacle comprising:
a third interior receptacle surface finding and interior receptacle chamber, the boot contacting the third interior receptacle surface;
a top;
a first opening at the top of the receptacle;
a bottom;
a second opening in the bottom in fluid communication with the interior passageways of the turbine airfoil and the exterior environment; and
second sidewalls connecting the top and bottom.

12. The turbine airfoil coating assembly of claim 10, further comprising a barrier coating on the root portion of the exterior surface, wherein the barrier coating does not block the interior passageway surfaces from being in fluid communication with the exterior environment.

13. The turbine airfoil coating assembly of claim 11, further comprising a barrier coating on the root portion of the exterior surface, wherein the barrier coating does not block the interior passageway surfaces from being in fluid communication with the exterior environment.

14. The apparatus of claim 12, wherein the barrier coating material is selected from the group consisting of a putty strip and a tape strip.

15. The apparatus of claim 14 wherein the barrier coating material further comprises a coating material selected from the group consisting of metallic powder, metal powder, and combinations thereof.

16. The apparatus of claim 13, wherein the barrier coating material is selected from the group consisting of a putty strip and a tape strip.

17. The apparatus of claim 16, wherein the barrier coating material further comprises a coating material selected from the group consisting of metallic powder, metal powder, and combinations thereof.

18. The apparatus of claim 17, wherein the barrier coating material further comprises nickel powder and chromium oxide powder.

19. The apparatus of claim 17, wherein the barrier coating material further comprises nickel powder and aluminum oxide powder.

20. A method for applying a diffusion aluminide coating to a turbine airfoil comprising the steps of:
providing a vapor phase diffusion aluminiding apparatus;
providing a plurality of graphite sponge boot sections, the graphite sponge boot sections being configured such that the graphite boot sections are capable of being assembled to form a graphite sponge boot comprising:
a first interior surface, the first interior surface defining a first interior cavity;
a first exterior surface;
a first aperture in the first exterior surface, the turbine airfoil extending out of the boot through the first exterior surface;
a second exterior surface;
a second aperture in the second exterior surface in fluid communication with the interior cavity, the interior passageway surface, and an exterior environment; and
first sidewalls connecting the first and second exterior surfaces, providing a boot receptacle, the boot receptacle comprising:
a third interior receptacle surface defining an interior receptacle chamber;
a top;
a first opening in the top of the receptacle permitting the insertion of the boot into the chamber;
a bottom;
a second opening in the bottom in fluid communication with the interior passageways of the turbine airfoil and the exterior environment; and
second sidewalls connecting the top and the bottom;
providing a turbine airfoil, the turbine airfoil comprising:
an airfoil section, a platform section, a dovetail section opposed to the airfoil section, the airfoil section extending in a first direction from the platform section, the dovetail section extending in a second direction from the platform section;
the airfoil section having an exterior flowpath surface;
the platform section having an exterior platform surface;
a plurality of interior passage surfaces, the plurality of interior passageway surfaces defining a plurality of cooling passageways and being in fluid communication with an exterior environment through a first plurality of cooling holes in the exterior flowpath surface and a second plurality of air intake holes in the root portion of the dovetail section;
the dovetail section having an exterior dovetail surface, the dovetail surface comprising a main portion and a root portion;
the plurality of interior passageways being in fluid communication with an exterior environment through a first plurality of cooling holes in the exterior flowpath surface and a second plurality of air intake holes in the root portion of the dovetail section;
applying a barrier coating to the root portion of the dovetail surface, such that the root portion of the dovetail surface is converted with the barrier coating and the second plurality of air intake holes remain in fluid communication with the exterior environment;
placing the graphite sponge boot sections around the dovetail section of the turbine airfoil such that substantially all of an exterior dovetail surface, excepting the root portion of the exterior dovetail surface, is in contact with the dovetail graphite sponge boot, such that all of the cooling holes are in fluid communication with an exterior environment;
inserting the dovetail graphite sponge boot into a boot receptacle such that all of the cooling holes are in fluid communication with an exterior environment;
inserting the boot receptacle into a vapor phase diffusion aluminiding apparatus; and
applying a diffusion aluminide layer to the exterior flowpath surface, the exterior platform surface, and the plurality of interior passageway surfaces of the turbine airfoil.
